(19) United States
(12) Patent Application Publication
(10) Pub. No.: US 2026/0262400 A1
(43) Pub. Date: Sep. 3, 2026

(54) DISPLAY SUBSTRATE AND DISPLAY DEVICE

(71) Applicant: BOE TECHNOLOGY GROUP CO., LTD., Beijing (CN)

(72) Inventor: Tian Dong, Beijing (CN)

(73) Assignee: BOE TECHNOLOGY GROUP CO., LTD., Beijing (CN)

(21) Appl. No.: 18/993,204

(22) PCT Filed: Aug. 13, 2024
(86) PCT No.: PCT/CN2024/111610

§ 371 Date: Jan. 10, 2025

(30) Foreign Application Priority Data
Sep. 22, 2023 (CN) 202311238735.3

(51) Int. Cl. H10K 59/131; H10K 59/121

(52) U.S. Cl. CPC H10K 59/131; H10K 59/1213

(57) ABSTRACT

The present disclosure provides a display substrate, where a plurality of sub-pixel driving circuits are divided into a plurality of columns. A plurality of data lines are divided into a plurality of groups, each group includes two adjacent data lines. One data line in the data line group is respectively coupled to odd-numbered sub-pixel driving circuits in a corresponding column of sub-pixel driving circuit columns, and the other data line in the data line group is respectively coupled to even-numbered sub-pixel driving circuits in a corresponding column of sub-pixel driving circuit columns. The display further includes a plurality of first signal lines configured to transmit a first signal with a stable potential. At least a portion of an orthographic projection of the first signal line on the base substrate is located between orthographic projections of two adjacent data lines in the corresponding data line group on the base substrate.

### CROSS-REFERENCE TO RELATED APPLICATION

The present application claims priority to the Chinese patent application No. 202311238735.3 filed in China on Sep. 22, 2023, a disclosure of which is incorporated herein by reference in its entirety.

### TECHNICAL FIELD

The present disclosure relates to the field of display technology, in particular to a display substrate and a display device.

### BACKGROUND

With the continuous development of display technologies, there are more and more types of display products. Active-matrix organic light-emitting diode (AMOLED), with their advantages of a wide color gamut, low cost, capability for large sizes, and ultra-thin designs, are widely used in various fields. However, current display products still need improvements in achieving both high frame rate display and high display yield.

### SUMMARY

An objective of the present disclosure is to provide a display substrate and a display device.

In order to achieve the foregoing objective, the present disclosure provides the following technical solutions:

A first aspect of the present disclosure provides a display substrate, including: a base substrate, a plurality of sub-pixels and data lines on the base substrate;
where the sub-pixel includes a sub-pixel driving circuit, a plurality of sub-pixel driving circuits included in the plurality of sub-pixels are distributed in an array, and the plurality of sub-pixel driving circuits are divided into a plurality of columns of sub-pixel driving circuit columns;
the plurality of data lines are divided into a plurality of groups of data line groups, the data line group includes two adjacent data lines; one data line in the data line group is respectively coupled to odd-numbered sub-pixel driving circuits in a corresponding column of sub-pixel driving circuit columns, and the other data line in the data line group is respectively coupled to even-numbered sub-pixel driving circuits in a corresponding column of sub-pixel driving circuit columns;
the display substrate further includes a plurality of first signal lines configured to transmit a first signal with a stable potential, at least a portion of an orthographic projection of the first signal line on the base substrate is located between orthographic projections of two adjacent data lines in the corresponding data line group on the base substrate.

Optionally, the display substrate further includes a plurality of second signal lines configured to transmit a second signal with a stable potential, at least a portion of an orthographic projection of the second signal line on the base substrate is located between orthographic projections of two adjacent data lines in different data line groups on the base substrate.

Optionally, the first signal line is close to a middle region of a layout region where a corresponding column of sub-pixel driving circuits columns is located, one data line in the data line group is close to a first side region of a layout region where a corresponding column of sub-pixel driving circuits columns is located, the other data line in the data line group is close to a second side region of a layout region where a corresponding column of sub-pixel driving circuits columns is located, and the middle region is located between the first side region and the second side region.

Optionally, the second signal line includes a reference signal line, the reference signal line includes at least a portion extending in a first direction, at least a portion of the reference signal line and a layout region of the sub-pixel driving circuit columns are alternately arranged in a second direction, and the reference signal line is coupled to a corresponding sub-pixel driving circuit.

Optionally, the reference signal line includes a reference signal main body portion and a plurality of reference signal connection portions, the plurality of reference signal connection portions are respectively coupled to the reference signal main body portion, the reference signal main body portion includes at least a portion extending in the first direction, and the reference signal main body portion and the layout region of the sub-pixel driving circuit columns are alternately arranged in the second direction;
the plurality of reference signal lines in the display substrate include a first-type reference signal line, a second-type reference signal line, a third-type reference signal line, and a fourth-type reference signal line;
the first-type reference signal line is respectively coupled to odd-numbered sub-pixel driving circuits in a sub-pixel driving circuit column adjacent to a first side of the first-type reference signal line, and the first-type reference signal line is respectively coupled to odd-numbered sub-pixel driving circuits in a sub-pixel driving circuit column adjacent to a second side of the first-type reference signal line;
the second-type reference signal line is respectively coupled to even-numbered sub-pixel driving circuits in a sub-pixel driving circuit column adjacent to a first side of the second-type reference signal line, and the second-type reference signal line is respectively coupled to odd-numbered sub-pixel driving circuits in a sub-pixel driving circuit column adjacent to a second side of the second-type reference signal line;
the third-type reference signal line is respectively coupled to even-numbered sub-pixel driving circuits in a sub-pixel driving circuit column adjacent to a first side of the third-type reference signal line, and the third-type reference signal line is respectively coupled to even-numbered sub-pixel driving circuits in a sub-pixel driving circuit column adjacent to a second side of the third-type reference signal line;
the fourth-type reference signal line is respectively coupled to odd-numbered sub-pixel driving circuits in a sub-pixel driving circuit column adjacent to a first side of the fourth-type reference signal line, and the second-type reference signal line is respectively coupled to an even-numbered sub-pixel driving circuit in a sub-pixel driving circuit column adjacent to a second side of the second-type reference signal line.

Optionally, the plurality of sub-pixel driving circuits are divided into a plurality of rows of sub-pixel driving circuit rows, the display substrate further includes a plurality of second initialization signal lines, the second initialization signal line extends in the second direction, and the second initialization signal line is respectively coupled to each sub-pixel driving circuit in a corresponding row of sub-pixel driving circuit rows.

Optionally, the second signal line includes a reference signal line and a second initialization signal line, the reference signal line includes at least a portion extending in a first direction, the reference signal line is coupled to a corresponding sub-pixel driving circuit, the second initialization signal line includes at least a portion extending in the first direction, and the second initialization signal line is coupled to a corresponding sub-pixel driving circuit;
at least a portion of the reference signal line and at least a portion of the second initialization signal line are alternately arranged in a second direction, at least a portion of the layout region of the sub-pixel driving circuit columns is located between the adjacent reference signal line and second initialization signal line.

Optionally, the plurality of reference signal lines in the display substrate include a fifth-type reference signal line;
the fifth-type reference signal line is respectively coupled to each sub-pixel driving circuit in a sub-pixel driving circuit column adjacent to a first side of the fifth-type reference signal line, and the fifth-type reference signal line is respectively coupled to each sub-pixel driving circuit in a sub-pixel driving circuit column adjacent to a second side of the fifth-type reference signal line.

Optionally, the plurality of sub-pixel driving circuits are divided into a plurality of rows of sub-pixel driving circuit rows, the display substrate further includes a plurality of second compensation initialization lines, the second compensation initialization line includes at least a portion extending in the second direction, and the second compensation initialization line is respectively coupled to each sub-pixel driving circuit in a corresponding row of sub-pixel driving circuit rows;
the second initialization signal line is respectively coupled to the plurality of second compensation initialization lines.

Optionally, the display substrate further includes a cathode layer and a plurality of cathode compensation lines, the cathode compensation line includes at least a portion extending in the first direction, and the cathode compensation line is coupled to the cathode layer;
an orthographic projection of the cathode compensation line on the base substrate and the orthographic projection of the first signal line on the base substrate are alternately arranged in the second direction.

Optionally, the orthographic projection of the cathode compensation line on the base substrate at least partially overlaps with the orthographic projection of the second signal line on the base substrate.

Optionally, the first signal line includes a power line, the power line includes at least a portion extending in the first direction, the power line is respectively coupled to each sub-pixel driving circuit in a corresponding column of sub-pixel driving circuit columns, the display substrate further includes a plurality of first power compensation lines, the first power compensation line includes at least a portion extending in the second direction, at least a portion of the first power compensation line is located between the base substrate and the power line, and the first power compensation line is coupled to the power line.

Optionally, the plurality of sub-pixel driving circuits are divided into a plurality of rows of sub-pixel driving circuit rows, the second signal line includes a power line, the power line includes at least a portion extending in a first direction, the display substrate further includes a plurality of first power compensation lines, the first power compensation line includes at least a portion extending in a second direction, the first power compensation line is respectively coupled to each sub-pixel driving circuit in a corresponding row of sub-pixel driving circuit rows, at least a portion of the first power compensation line is located between the power line and the base substrate, and the power line is respectively coupled to the plurality of first power compensation lines.

Optionally, the display substrate further includes a plurality of second power compensation lines, the second power compensation line includes at least a portion extending in the first direction, and at least a portion of the second power compensation line is located between the first power compensation line and the power line;
an orthographic projection of the second power compensation line on the base substrate at least partially overlaps with an orthographic projection of the corresponding power line on the base substrate, and the second power compensation line is respectively coupled to the corresponding power line and the plurality of first power compensation lines.

Optionally, the first signal line includes a reference signal line, the reference signal line includes at least a portion extending in the first direction, and the reference signal line is respectively coupled to each sub-pixel driving circuit in a corresponding column of sub-pixel driving circuit columns.

Optionally, the display substrate further includes a plurality of second initialization signal lines, the second initialization signal line includes at least a portion extending in the second direction, and the second initialization signal line is respectively coupled to each sub-pixel driving circuit in a corresponding row of sub-pixel driving circuit rows.

Optionally, the first signal line includes a second initialization signal line, the second initialization signal line includes at least a portion extending in the first direction, and the second initialization signal line is respectively coupled to each sub-pixel driving circuit in a corresponding column of sub-pixel driving circuit columns.

Optionally, the display substrate further includes a plurality of reference signal lines, the reference signal line includes at least a portion extending in the second direction, and the reference signal line is respectively coupled to each sub-pixel driving circuit in a corresponding row of sub-pixel driving circuit rows.

Optionally, the plurality of sub-pixel driving circuits are divided into a plurality of rows of sub-pixel driving circuit rows, the display substrate further includes a plurality of first initialization signal lines, the first initialization signal line extends in a second direction, and the first initialization signal line is respectively coupled to each sub-pixel driving circuits in a corresponding row of sub-pixel driving circuit rows.

Based on the technical solution of the foregoing display substrate, a second aspect of the present disclosure provides a display device, including the foregoing display substrate.

### BRIEF DESCRIPTION OF THE DRAWINGS

The drawings described herein are used to provide a further understanding of the present disclosure and constitute a part of the disclosure. The exemplary embodiments of the disclosure and the descriptions thereof are used to explain the disclosure, and do not constitute improper limitations to the disclosure. In the drawings:

FIG. 1 is a circuit structure diagram of a sub-pixel driving circuit according to an embodiment of the present disclosure;

FIG. 2 is a cross-sectional diagram of a film layer of a display substrate according to an embodiment of the present disclosure;

FIG. 3 is a schematic diagram of a layout manner of a sub-pixel according to an embodiment of the present disclosure;

FIG. 4 is a schematic diagram of a first layout of a second gate metal layer, a first source-drain metal layer and a second source-drain metal layer according to an embodiment of the present disclosure;

FIG. 5 is a schematic diagram of a layout of a first source-drain metal layer in FIG. 4;

FIG. 6 is a schematic diagram of a layout of a second source-drain metal layer in FIG. 4;

FIG. 7 is a schematic diagram of a second layout of a second gate metal layer, a first source-drain metal layer and a second source-drain metal layer according to an embodiment of the present disclosure;

FIG. 8 is a schematic diagram of a layout of a first source-drain metal layer in FIG. 7;

FIG. 9 is a schematic diagram of a layout of a second source-drain metal layer in FIG. 7;

FIG. 10 is a schematic diagram of a third layout of a second gate metal layer, a first source-drain metal layer and a second source-drain metal layer according to an embodiment of the present disclosure;

FIG. 11 is a schematic diagram of a layout of a first source-drain metal layer in FIG. 10;

FIG. 12 is a schematic diagram of a layout of a second source-drain metal layer in FIG. 10;

FIG. 13 is a schematic diagram of a fourth layout of a second gate metal layer, a first source-drain metal layer and a second source-drain metal layer according to an embodiment of the present disclosure;

FIG. 14 is a schematic diagram of a layout of a first source-drain metal layer in FIG. 13;

FIG. 15 is a schematic diagram of a layout of a second source-drain metal layer in FIG. 13;

FIG. 16 is a schematic diagram of a fifth layout of a second gate metal layer, a first source-drain metal layer and a second source-drain metal layer according to an embodiment of the present disclosure;

FIG. 17 is a schematic diagram of a layout of a first source-drain metal layer in FIG. 16;

FIG. 18 is a schematic diagram of a layout of a second source-drain metal layer in FIG. 16.

### DETAILED DESCRIPTION

In order to further describe the display substrate and the display device provided by the embodiments of the present disclosure, a detailed description is made below combining with the accompanying drawings.

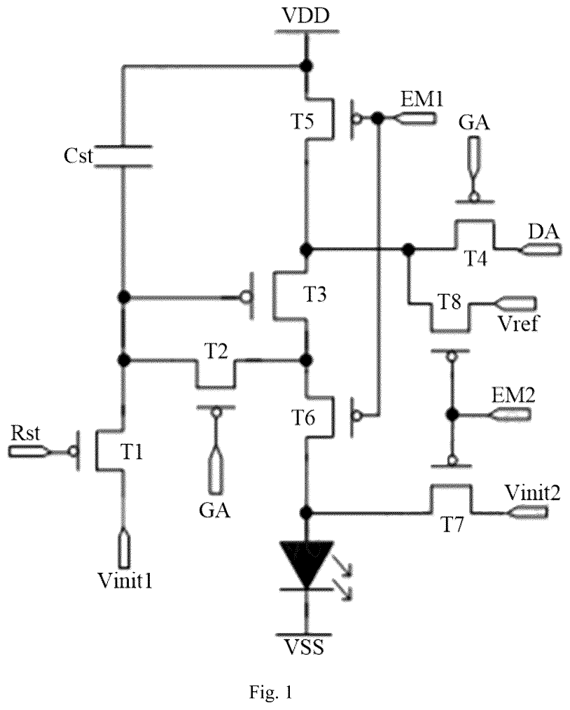

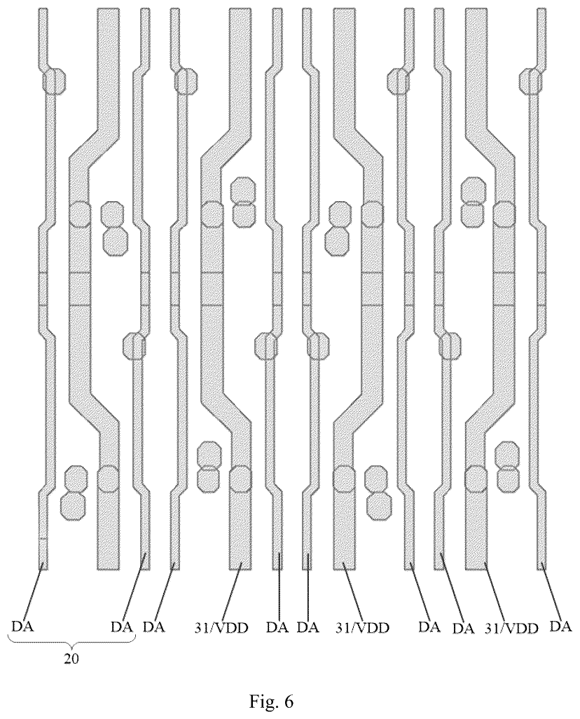

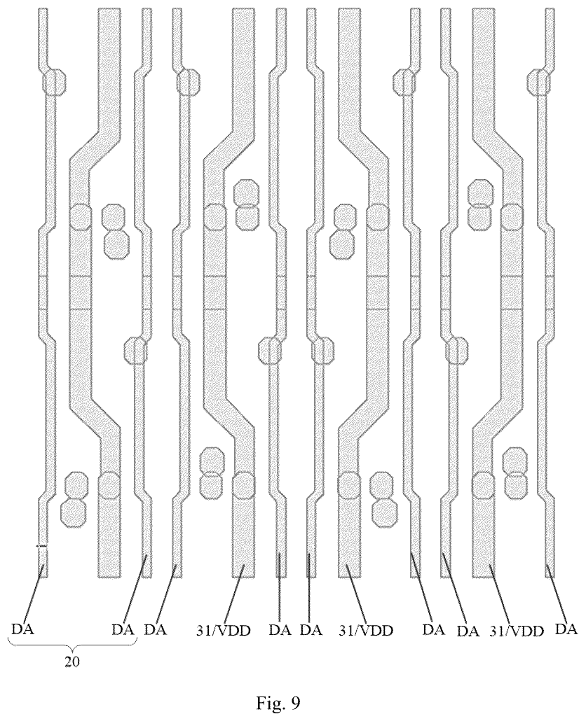

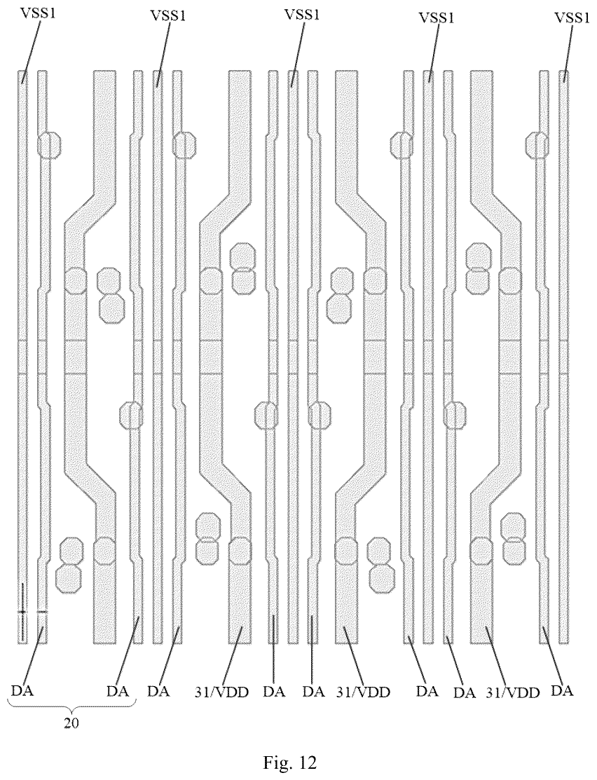

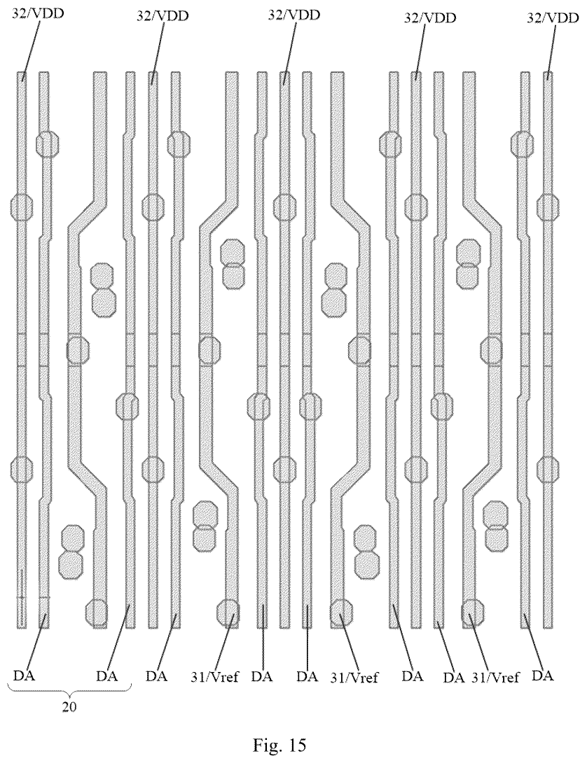

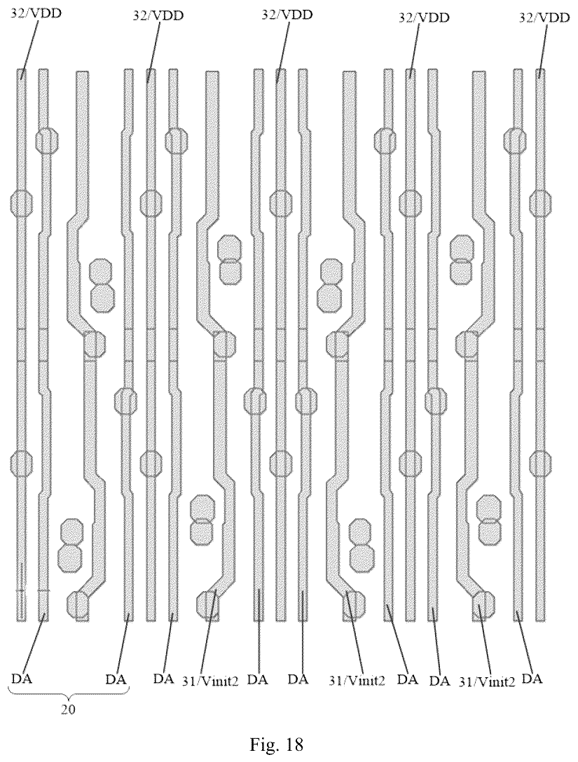

Referring to FIG. 1 and FIG. 3 to FIG. 18, one embodiment of the present disclosure provides a display substrate, including: a base substrate, a plurality of sub-pixels and data lines DA on the base substrate;
where the sub-pixel includes a sub-pixel driving circuit, a plurality of sub-pixel driving circuits included in the plurality of sub-pixels are distributed in an array, and the plurality of sub-pixel driving circuits are divided into a plurality of columns of sub-pixel driving circuit columns;
the plurality of data lines DA are divided into a plurality of groups of data line groups 20, the data line group 20 includes two adjacent data lines DA; one data line DA in the data line group 20 is respectively coupled to odd-numbered sub-pixel driving circuits in a corresponding column of sub-pixel driving circuit columns, and the other data line DA in the data line group 20 is respectively coupled to even-numbered sub-pixel driving circuits in a corresponding column of sub-pixel driving circuit columns;
the display substrate further includes a plurality of first signal lines 31 configured to transmit a first signal with a stable potential, at least a portion of an orthographic projection of the first signal line 31 on the base substrate is located between orthographic projections of two adjacent data lines DA in the corresponding data line group 20 on the base substrate.

Exemplarily, the display substrate includes a plurality of sub-pixels, and a plurality of sub-pixel driving circuits included in the plurality of sub-pixels are distributed in an array. The plurality of sub-pixel driving circuits are divided into a plurality of rows of sub-pixel driving circuit rows and a plurality of columns of sub-pixel driving circuit columns. The plurality of rows of sub-pixel driving circuits rows are arranged in a first direction, and each row of sub-pixel driving circuit rows includes a plurality of sub-pixel driving circuits arranged in a second direction. The plurality of columns of sub-pixel driving circuit columns are arranged in a second direction, and each column of sub-pixel driving circuit columns includes a plurality of sub-pixel driving circuits arranged in a first direction. Exemplarily, the first direction intersects with the second direction. For example, the first direction includes a longitudinal direction, and the second direction includes a transverse direction.

Exemplarily, tthe pixel arrangement uses AABB (Blue Green Red Green) and BBAA (Red Green Blue Green) design, and the A sub-pixel driving circuit structure and the B sub-pixel driving circuit structure are arranged in a substantially symmetrical manner. The red sub-pixel adopts a B sub-pixel driving circuit structure. The blue sub-pixel adopts the A sub-pixel driving circuit structure. The green sub-pixel alternately adopts the A sub-pixel driving circuit structure and the B sub-pixel driving circuit structure. This layout mode can solve the problems of displaying transverse line and the vertical line in the conventional arrangement.

Exemplarily, the sub-pixel includes a sub-pixel driving circuit and a light-emitting element. The sub-pixel driving circuit is coupled to an anode of the light-emitting element, and is configured to provide a driving signal for the light-emitting element to drive the light-emitting element to emit light.

Exemplarily, the display substrate includes the plurality of data lines DA arranged in the second direction, the data line DA includes at least a portion extending along the first direction, and the data line DA is configured to transmit a data signal. The plurality of data lines DA are divided into a plurality of groups of data line groups 20 arranged in the second direction, and the data line group 20 includes two adjacent data lines DA.

Exemplarily, the plurality of groups of data line groups 20 are in one-to-one correspondence with the plurality of columns of sub-pixel driving circuit columns. One data line DA in the data line group 20 is respectively coupled to odd-numbered sub-pixel driving circuits in a corresponding column of sub-pixel driving circuit columns, and is configured to provide a data signal for each odd-numbered sub-pixel driving circuit. The other data line DA in the data line group 20 is respectively coupled to even-numbered sub-pixel driving circuits in a corresponding column of sub-pixel driving circuit columns, and is configured to provide a data signal for each even-numbered sub-pixel driving circuit.

Exemplarily, the display substrate further includes a plurality of first signal lines 31 arranged in the second direction, the first signal line 31 includes at least a portion extending in the first direction, and the first signal lines 31 are configured to transmit a first signal with a stable potential.

Exemplarily, the sub-pixel driving circuit adopts a Low Temperature Poly-Silicon (LTPS) technology, but is not limited thereto.

Exemplarily, the sub-pixel driving circuit uses 8T1C (i.e., 8 transistors and 1 storage capacitor) circuit structure. Each transistor included in the sub-pixel driving circuit is an LTPS transistor.

As shown in FIG. 1, exemplarily, the display substrate includes a scan line GA, a reset signal line RST, a first light emission control signal line EM1, a second light emission control signal line EM2, a first initialization signal line Vinit1, a second initialization signal line Vinit2, a power line Vdd, a data line DA, and a reference signal line Vref. The sub-pixel driving circuit includes a driving transistor T3, a compensation transistor T2, a data writing transistor T4, a first reset transistor T1, a second reset transistor T7, a power control transistor T5, a light-emitting control transistor T6, a node control transistor T8, and a storage capacitor Cst.

A gate of the first reset transistor T1 is coupled to the corresponding reset signal line Rst, a first electrode of the first reset transistor T1 is coupled to the first initialization signal line Vinit1, and a second electrode of the first reset transistor T1 is coupled to a gate of the driving transistor T3.

A gate of the compensation transistor T2 is coupled to the corresponding scan line GA, a first electrode of the compensation transistor T2 is coupled to a second electrode of the driving transistor T3, and a second electrode of the compensation transistor T2 is coupled to a gate of the driving transistor T3.

A gate of the data writing transistor T4 is coupled to the corresponding scan line GA, a first electrode of the data writing transistor T4 is coupled to the corresponding data line DA, and a second electrode of the data writing transistor T4 is coupled to a first electrode of the drive transistor T3.

A gate of the power control transistor T5 is coupled to the corresponding first light-emitting control signal line EM1, a first electrode of the power control transistor T5 is coupled to a corresponding power line VDD, and a second electrode of the power control transistor T5 is coupled to a first electrode of the driving transistor T3.

A gate of the light-emitting control transistor T6 is coupled to the corresponding first light-emitting control signal line EM1, a first electrode of the light-emitting control transistor T6 is coupled to a second electrode of the driving transistor T3, a second electrode of the light-emitting control transistor T6 is coupled to an anode of the corresponding light-emitting element, and a cathode of the light-emitting element receives a negative power signal VSS.

A gate of the second reset transistor T7 is coupled to a corresponding second light-emitting control signal line EM2, a first electrode of the second reset transistor T7 is coupled to the corresponding second initialization signal line Vinit2, and a second electrode of the second reset transistor T7 is coupled to an anode of the corresponding light-emitting element.

A gate of the node control transistor T8 is coupled to the corresponding second light-emitting control signal line EM2, a first electrode of the node control transistor T8 is coupled to a corresponding reference signal line Vref, and a second electrode of the node control transistor T8 is coupled to a first electrode of the driving transistor T3.

A first electrode plate of the storage capacitor Cst is coupled to a gate electrode of the driving transistor T3, and a second electrode plate of the storage capacitor Cst is coupled to the corresponding power line VDD.

According to the specific structure of the foregoing display substrate, it can be known that in the display substrate provided by the embodiment of the present disclosure, a dual data link (DDL) technology is used, so that each column of sub-pixel driving circuit columns corresponds to two data lines DA. One data line DA is configured to provide a data signal for the odd-numbered sub-pixel driving circuit, and the other data line DA is configured to provide a data signal for the even-numbered sub-pixel driving circuit, so that each sub-pixel driving circuit has sufficient charging time, and it is ensured that the display substrate can reduce power consumption of a chip used for providing a data signal in the display substrate while achieving high-frame-frequency display.

Moreover, in the display substrate provided by the embodiment of the present disclosure, the sub-pixel driving circuit adopts an LTPS circuit structure, so that the display substrate can realize a low-cost and low-frequency driving mode. In the display substrate provided by the embodiment of the present disclosure, DDL technology and LTPS technology are combined, so that power consumption is greatly reduced while low-cost and full-frame-frequency driving (that is, low-frame-frequency driving and high-frame-frequency driving can be achieved) are achieved.

In addition, in the display substrate provided by the embodiment of the present disclosure, at least a portion of an orthographic projection of the first signal line 31 on the base substrate is arranged between orthographic projections of two adjacent data lines DA in the corresponding data line group 20 on the base substrate. Since the first signal line 31 is configured to transmit a first signal with a stable potential, the first signal line 31 can well shield crosstalk between two adjacent data lines DA in the data line group 20, thereby effectively improving the display yield and display quality of the display substrate.

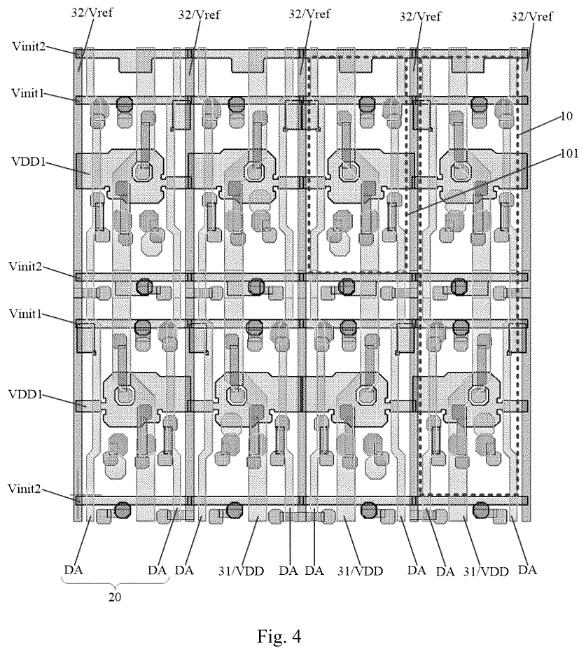

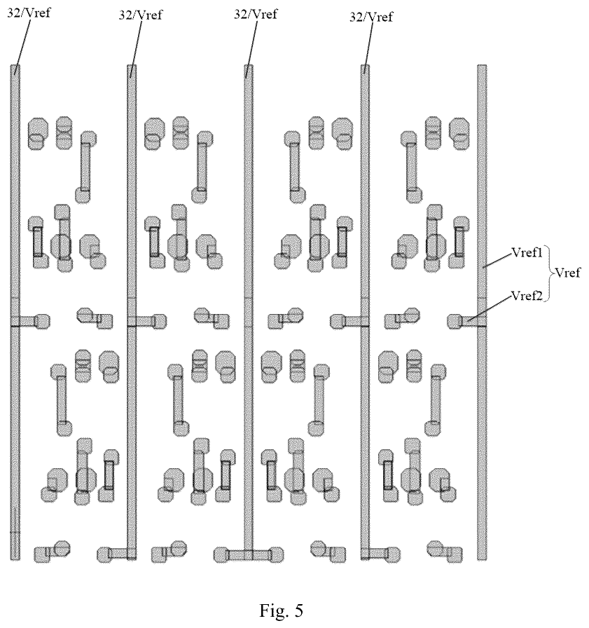

As shown in FIG. 4 to FIG. 18, in some embodiments, the display substrate further includes a plurality of second signal lines 32 configured to transmit a second signal with a stable potential, at least a portion of an orthographic projection of the second signal line 32 on the base substrate is located between orthographic projections of two adjacent data lines DA in different data line groups 20 on the base substrate.

Exemplarily, the plurality of second signal lines 32 are arranged in the second direction, and the second signal lines 32 include at least a portion of the second signal lines 32 arranged in the first direction.

In the display substrate provided in the above embodiment, at least a portion of an orthographic projection of the second signal line 32 on the base substrate is arranged between orthographic projections of two adjacent data lines DA in different data line groups 20 on the base substrate. Since the second signal line 32 is configured to transmit a second signal with a stable potential, the second signal line 32 can reduce a parasitic capacitance formed between two adjacent data lines DA in different data line groups 20 and well shield crosstalk between two adjacent data lines DA in different data line groups 20, thereby effectively improving the display yield and display quality of the display substrate.

As shown in FIG. 4 to FIG. 18, in some embodiments, the first signal line 31 is close to a middle region of a layout region 10 where a corresponding column of sub-pixel driving circuits columns is located, one data line DA in the data line group 20 is close to a first side region of a layout region 10 where a corresponding column of sub-pixel driving circuits columns is located, the other data line DA in the data line group 20 is close to a second side region of a layout region 10 where a corresponding column of sub-pixel driving circuits columns is located, and the middle region is located between the first side region and the second side region.

It should be noted that the layout region 10 where one column of sub-pixel driving circuit columns is located is the layout region occupied by all the sub-pixel driving circuits in the column of sub-pixel driving circuit columns. The layout region 101 occupied by each sub-pixel driving circuit may be a region capable of accommodating the sub-pixel driving circuit. Exemplarily, the region may be selected as a rectangular region, but is not limited thereto.

The above layout manner enables the data line DA to be far away from the key node in the pixel driving circuit as much as possible while being coupled to the corresponding sub-pixel driving circuit, such as the conductive connection portion (i.e., the N1 node) respectively connected to the gate of the driving transistor and the second electrode of the compensation transistor. This layout manner not only can improve the working stability of the sub-pixel driving circuit, but also can help to reduce the layout difficulty of the sub-pixel driving circuit.

As shown in FIG. 4 to FIG. 6, in some embodiments, the second signal line 32 includes a reference signal line Vref, and the reference signal line Vref includes at least a portion extending in the first direction, at least a portion of the reference signal line Vref and a layout region of the sub-pixel driving circuit columns are alternately arranged in the second direction, and the reference signal line Vref is coupled to a corresponding sub-pixel driving circuit.

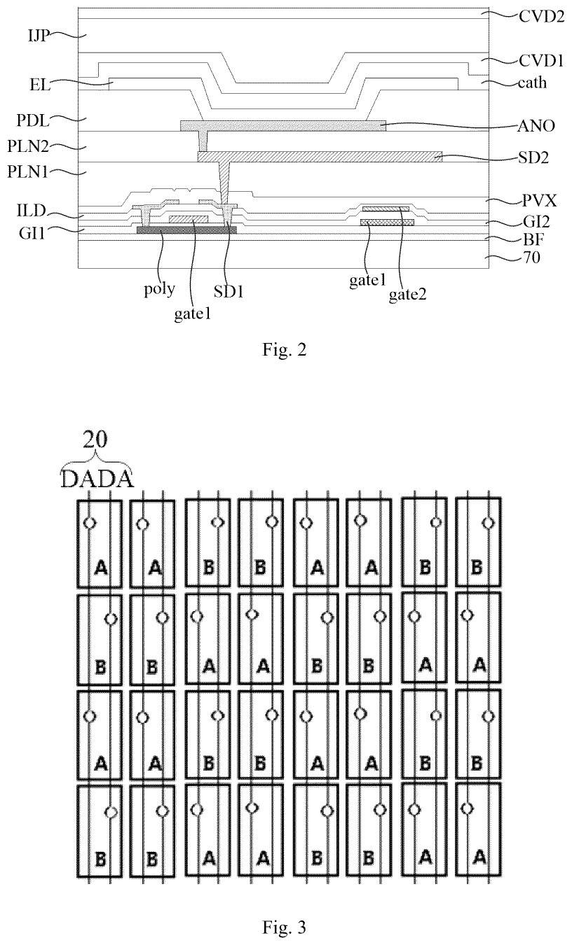

Exemplarily, as shown in FIG. 2, the display substrate includes a buffer layer BF, an active layer poly, a first gate insulating layer GI1, a first gate metal layer gate1, a second gate insulating layer GI2, a second gate metal layer gate2, an interlayer insulating layer ILD, a first source-drain metal layer SD1, a first planarization layer PLN1, a second source-drain metal layer SD2, a second planarization layer PLN2, an anode layer ANO, a light-emitting functional layer EL, a cathode layer cath, a first inorganic encapsulation layer CVD1, an organic encapsulation layer IJP, and a second inorganic encapsulation layer CVD2 sequentially stacked in a direction away from the base substrate 70. The display substrate may further include a passivation layer PVX, but is not limited to.

Exemplarily, the reference signal line Vref is configured to provide a reference signal. The reference signal line Vref and the first source-drain metal layer are arranged in a same layer and made of a same material.

Exemplarily, the reference signal line Vref includes a reference signal main body portion Vref1 and a plurality of reference signal connection portions Vref2, the plurality of reference signal connection portions Vref2 are respectively coupled to the reference signal main body portion Vref1, the reference signal main body portion Vref1 includes at least a portion extending in the first direction, and the reference signal main body portion Vref1 and the layout region 10 of the sub-pixel driving circuit columns are alternately arranged in the second direction;
the plurality of reference signal lines Vref in the display substrate include a first-type reference signal line Vref, a second-type reference signal line Vref, a third-type reference signal line Vref, and a fourth-type reference signal line Vref;
the first-type reference signal line Vref is respectively coupled to odd-numbered sub-pixel driving circuits in a sub-pixel driving circuit column adjacent to a first side of the first-type reference signal line Vref, and the first-type reference signal line Vref is respectively coupled to odd-numbered sub-pixel driving circuits in a sub-pixel driving circuit column adjacent to a second side of the first-type reference signal line Vref;
the second-type reference signal line Vref is respectively coupled to even-numbered sub-pixel driving circuits in a sub-pixel driving circuit column adjacent to a first side of the second-type reference signal line Vref, and the second-type reference signal line Vref is respectively coupled to odd-numbered sub-pixel driving circuits in a sub-pixel driving circuit column adjacent to a second side of the second-type reference signal line Vref;
the third-type reference signal line Vref is respectively coupled to even-numbered sub-pixel driving circuits in a sub-pixel driving circuit column adjacent to a first side of the third-type reference signal line Vref, and the third-type reference signal line Vref is respectively coupled to even-numbered sub-pixel driving circuits in a sub-pixel driving circuit column adjacent to a second side of the third-type reference signal line Vref;
the fourth-type reference signal line Vref is respectively coupled to odd-numbered sub-pixel driving circuits in a sub-pixel driving circuit column adjacent to a first side of the fourth-type reference signal line Vref, and the second-type reference signal line Vref is respectively coupled to an even-numbered sub-pixel driving circuit in a sub-pixel driving circuit column adjacent to a second side of the second-type reference signal line Vref.

Exemplarily, the reference signal main body portion Vref1 and the plurality of reference signal connection portions Vref2 included in the reference signal line Vref are formed as an integrated structure.

Exemplarily, the reference signal connection portion Vref2 is coupled to a first electrode of the node control transistor in a corresponding sub-pixel driving circuit.

Exemplarily, the reference signal line Vref may further include two edge reference signal lines Vref, one of the edge reference signal lines Vref is close to the first side of the whole display substrate, and the other of the edge reference signal lines Vref is close to the second side of the whole display substrate. One of the edge reference signal lines Vref is respectively coupled to odd-numbered sub-pixel driving circuits in a column of sub-pixel driving circuit columns on the outermost edge of the first side of the display substrate. The other of the edge reference signal line Vref is respectively coupled to even-number sub-pixel driving circuits in a column of sub-pixel driving circuit columns on the outermost edge of the second side of the display substrate. Alternatively, one of the edge reference signal lines Vref is respectively coupled to even-numbered sub-pixel driving circuits in a column of sub-pixel driving circuit columns on the outermost edge of the first side of the display substrate. The other of the edge reference signal line Vref is respectively coupled to odd-number sub-pixel driving circuits in a column of sub-pixel driving circuit columns on the outermost edge of the second side of the display substrate.

In the foregoing arrangement, at least a portion of the orthogonal projection of the reference signal line Vref on the base substrate is arranged between orthogonal projections of two adjacent data lines DA in different data line groups 20 on the base substrate. Since the reference signal line Vref is configured to transmit a reference signal with a stable potential, the reference signal line Vref can reduce a parasitic capacitance formed between two adjacent data lines DA in different data line groups 20 and well shield crosstalk between two adjacent data lines DA in different data line groups 20, thereby effectively improving the display yield and display quality of the display substrate.

As shown in FIG. 4 to FIG. 6, in some embodiments, the plurality of sub-pixel driving circuits are divided into a plurality of rows of sub-pixel driving circuit rows, the display substrate further includes a plurality of second initialization signal lines Vinit2, the second initialization signal line Vinit2 extends in the second direction, and the second initialization signal line Vinit2 is respectively coupled to each sub-pixel driving circuit in a corresponding row of sub-pixel driving circuit rows.

Exemplarily, the plurality of rows of sub-pixel driving circuit rows are arranged in the first direction, and each row of sub-pixel driving circuit rows includes a plurality of sub-pixels arranged in the second direction.

Exemplarily, the second initialization signal line Vinit2 is configured to transmit a second initialization signal. The plurality of second initialization signal lines Vinit2 are in one-to-one correspondence with the plurality of rows of sub-pixel driving circuits, and the second initialization signal line Vinit2 is respectively coupled to a first electrode of the second reset transistor included in each sub-pixel driving circuit in a corresponding row of sub-pixel driving circuit rows.

Exemplarily, the second initialization signal line Vinit2 and the second gate metal layer are arranged in a same layer and made of a same material.

In the foregoing arrangement, the layout of the second initialization signal line Vinit2 and the reference signal line Vref is reasonably planned, which not only reduces the layout difficulty of the signal line, but also ensures the reliability and stability of signal transmission.

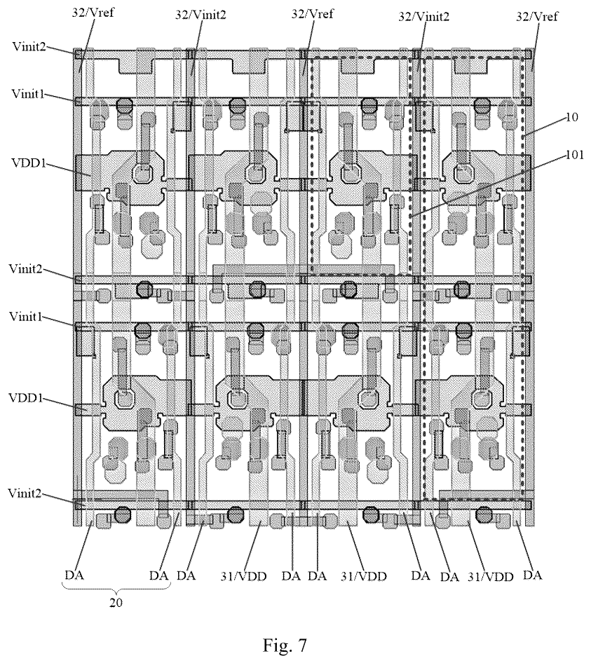

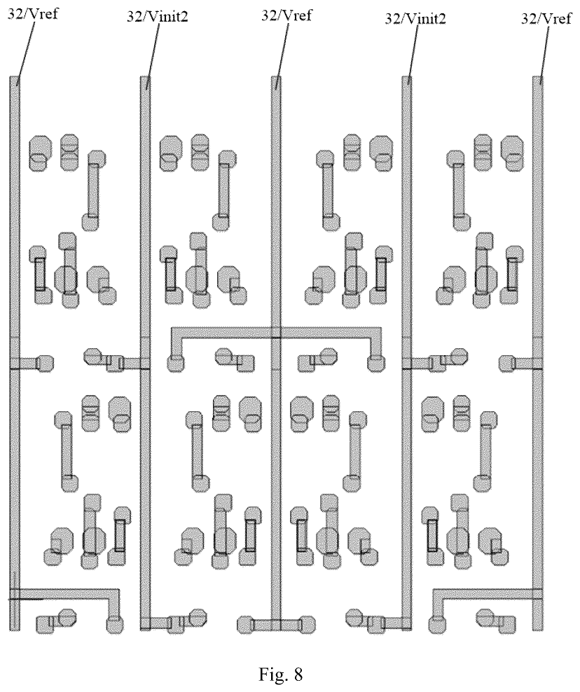

As shown in FIG. 7 to FIG. 9, in some embodiments, the second signal line 32 includes a reference signal line Vref and a second initialization signal line Vinit2, the reference signal line Vref includes at least a portion extending in a first direction, the reference signal line Vref is coupled to a corresponding sub-pixel driving circuit, the second initialization signal line Vinit2 includes at least a portion extending in the first direction, and the second initialization signal line Vinit2 is coupled to a corresponding sub-pixel driving circuit;
at least a portion of the reference signal line Vref and at least a portion of the second initialization signal line Vinit2 are alternately arranged in a second direction, at least a portion of the layout region of the sub-pixel driving circuit columns is located between the adjacent reference signal line Vref and second initialization signal line Vinit2.

Exemplarily, the reference signal line Vref and the second initialization signal line Vinit2 are both arranged in a same layer and made of a same material as the first source-drain metal layer.

Exemplarily, the plurality of reference signal lines Vref in the display substrate include a fifth-type reference signal line Vref; the fifth-type reference signal line Vref is respectively coupled to each sub-pixel driving circuit in a sub-pixel driving circuit column adjacent to a first side of the fifth-type reference signal line, and/or, the fifth-type reference signal line is respectively coupled to each sub-pixel driving circuit in a sub-pixel driving circuit column adjacent to a second side of the fifth-type reference signal line.

Exemplarily, the plurality of sub-pixel driving circuits are divided into a plurality of rows of sub-pixel driving circuit rows, the display substrate further includes a plurality of second compensation initialization lines, the second compensation initialization line includes at least a portion extending in the second direction, and the second compensation initialization line is respectively coupled to each sub-pixel driving circuit in a corresponding row of sub-pixel driving circuit rows; the second initialization signal line Vinit2 is respectively coupled to the plurality of second compensation initialization lines.

Exemplarily, the second compensation initialization line and the second gate metal layer are arranged in a same layer and made of a same material.

Exemplarily, the plurality of second compensation initialization lines are arranged in the first direction, and the plurality of second compensation initialization lines are in one-to-one correspondence with the plurality of rows of sub-pixel driving circuit rows. The second compensation initialization line is respectively coupled to a first electrode of the second reset transistor included in each sub-pixel driving circuit in a corresponding row of sub-pixel driving circuit rows.

In the foregoing arrangement, the display substrate includes a second compensation initialization line and a second initialization signal line Vinit2, so that the second compensation initialization line and second initialization signal line Vinit2 can be jointly formed as a grid-like structure for transmitting a second initialization signal. Therefore, the load of the film layer for transmitting the second initialization signal is effectively reduced, and the uniformity of the second initialization signal is improved.

In the foregoing arrangement manner, the reference signal line Vref and the second initialization signal line Vinit2 can reduce a parasitic capacitance formed between two adjacent data lines DA in different data line groups 20 and well shield crosstalk between two adjacent data lines DA in different data line groups 20, thereby effectively improving the display yield and display quality of the display substrate and the low gray scale display Mura of the display substrate.

In the foregoing arrangement, the layout of the second initialization signal line Vinit 2, the second compensation initialization line and the reference signal line Vref is reasonably planned, which not only reduces the layout difficulty of the signal line, but also ensures the reliability and stability of signal transmission.

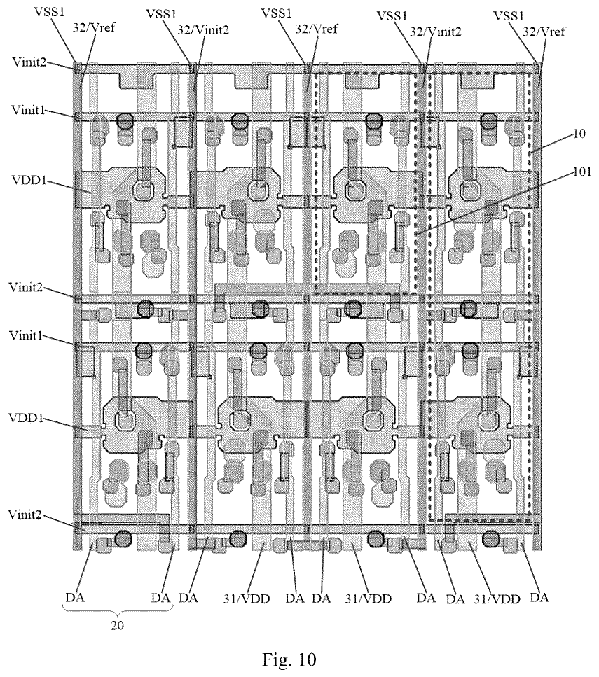

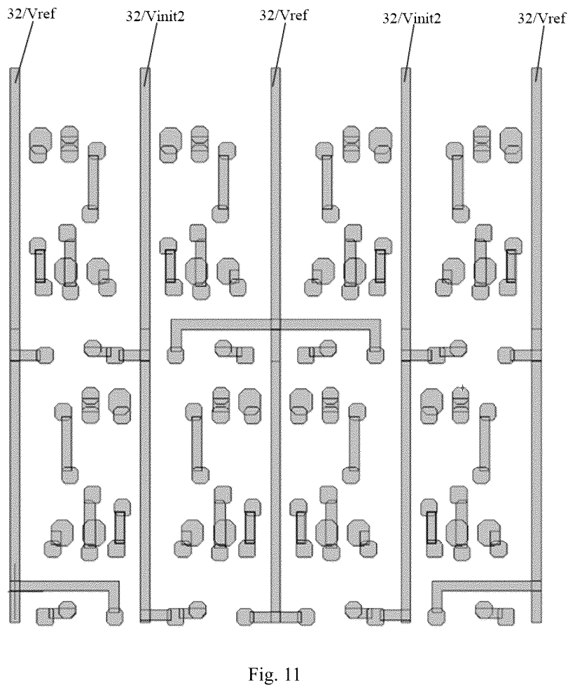

As shown in FIG. 10 to FIG. 12, in some embodiments, the display substrate further includes a cathode layer and a plurality of cathode compensation lines VSS1, the cathode compensation line VSS1 includes at least a portion extending in the first direction, and the cathode compensation line VSS1 is coupled to the cathode layer;
an orthographic projection of the cathode compensation line VSS1 on the base substrate and the orthographic projection of the first signal line 31 on the base substrate are alternately arranged in the second direction.

Exemplarily, the plurality of cathode compensation lines VSS1 are arranged in the second direction. The cathode compensation line VSS1 and the second source-drain metal layer are arranged in a same layer and made of a same material.

Exemplarily, the cathode layer is multiplexed as a cathode of the light-emitting element. The cathode compensation line VSS1 and the cathode layer may be coupled in a display region and/or a non-display region.

Exemplarily, the orthographic projection of the cathode compensation line VSS1 on the base substrate at least partially overlaps with the orthographic projection of the second signal line 32 on the base substrate.

Exemplarily, the orthographic projection of the cathode compensation line VSS1 on the base substrate at least partially overlaps with the orthographic projection of the reference signal line Vref on the base substrate.

Exemplarily, the orthographic projection of the cathode compensation line VSS1 on the base substrate at least partially overlaps with the orthographic projection of the initialization signal line on the base substrate.

The above arrangement is beneficial to improving the overall IR Drop of the cathode layer.

As shown in FIG. 4 to FIG. 12, in some embodiments, the first signal line 31 includes a power line VDD, the power line VDD includes at least a portion extending in the first direction, the power line VDD is respectively coupled to each sub-pixel driving circuit in a corresponding column of sub-pixel driving circuit columns, the display substrate further includes a plurality of first power compensation lines VDD1, the first power compensation line VDD1 includes at least a portion extending in the second direction, at least a portion of the first power compensation line VDD1 is located between the base substrate and the power line VDD, and the first power compensation line VDD1 is coupled to the power line VDD.

Exemplarily, the power line VDD and the second source-drain metal layer are arranged in a same layer and made of a same material. The first power compensation line VDD1 and the second gate metal layer are arranged in a same layer and made of a same material.

Exemplarily, the power line VDD is respectively coupled to a first electrode of the power control transistor included in each sub-pixel driving circuit in a corresponding column of sub-pixel driving circuit columns. The plurality of first power compensation lines VDD1 are in one-to-one correspondence with the plurality of rows of sub-pixel driving circuit rows, and the first power compensation line VDD1 is multiplexed as the second electrode plate of the storage capacitor in a corresponding row of sub-pixel driving circuit rows.

Exemplarily, the first power compensation line VDD1 is respectively coupled to the plurality of power lines VDD.

The above arrangement enables the power line VDD and the first power compensation line VDD1 to form a grid-shaped structure, which is beneficial to improving the overall IR Drop of the power line VDD and improving the display uniformity.

In the foregoing arrangement, at least a portion of an orthographic projection of the power line VDD on the base substrate is located between orthographic projections of two adjacent data lines DA in the corresponding data line group 20 on the base substrate. Since the power line VDD is configured to transmit a power signal with a stable potential, the power line VDD can well shield crosstalk between two adjacent data lines DA in the data line group 20, thereby effectively improving the display yield and the display quality of the display substrate.

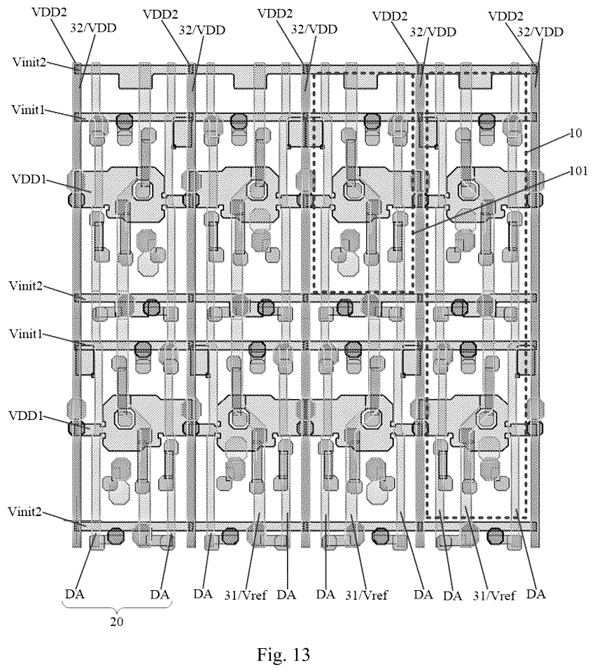

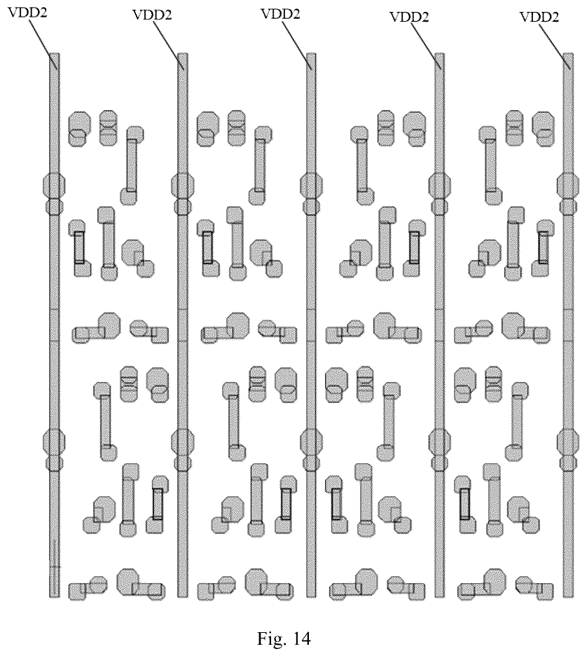

As shown in FIG. 13 to FIG. 18, in some embodiments, the plurality of sub-pixel driving circuits are divided into a plurality of rows of sub-pixel driving circuit rows, the second signal line 32 includes a power line VDD, the power line VDD includes at least a portion extending in a first direction;
the display substrate further includes a plurality of first power compensation lines VDD1, the first power compensation line VDD1 includes at least a portion extending in a second direction, the first power compensation line VDD1 is respectively coupled to each sub-pixel driving circuit in a corresponding row of sub-pixel driving circuit rows, at least a portion of the first power compensation line VDD1 is located between the power line VDD and the base substrate, and the power line VDD is respectively coupled to the plurality of first power compensation lines VDD1.

The above arrangement enables the power line VDD and the first power compensation line VDD1 to form a grid-shaped structure, which is beneficial to improving the overall IR Drop of the power line VDD and improving the display uniformity.

In the foregoing arrangement, the power line VDD can reduce a parasitic capacitance formed between two adjacent data lines DA in different data line groups 20 and well shield crosstalk between two adjacent data lines DA in different data line groups 20, thereby effectively improving the display yield and display quality of the display substrate and the low gray scale display Mura of the display substrate.

As shown in FIG. 13 to FIG. 18, in some embodiments, the display substrate further includes a plurality of second power compensation lines VDD2, the second power compensation line VDD2 includes at least a portion extending in the first direction, and at least a portion of the second power compensation VDD2 line is located between the first power compensation line VDD1 and the power line VDD; an orthographic projection of the second power compensation line VDD2 on the base substrate at least partially overlaps with an orthographic projection of the corresponding power line VDD on the base substrate, and the second power compensation line VDD2 is respectively coupled to the corresponding power line VDD and the plurality of first power compensation lines VDD1.

Exemplarily, the second power compensation line VDD2 and the first source-drain metal layer are arranged in a same layer and made of a same material.

Exemplarily, the plurality of second power compensation lines VDD2 are arranged in the second direction.

Exemplarily, the plurality of second power compensation lines VDD2 are in one-to-one correspondence with the plurality of power lines VDD.

The above arrangement enables the power line VDD, the first power compensation line VDD1 and the second power compensation line VDD2 to form a grid-shaped structure, which is beneficial to improving the overall IR Drop of the power line VDD and improving the display uniformity.

In the foregoing arrangement, the power line VDD can reduce a parasitic capacitance formed between two adjacent data lines DA in different data line groups 20 and well shield crosstalk between two adjacent data lines DA in different data line groups 20, thereby effectively improving the display yield and display quality of the display substrate and the low gray scale display Mura of the display substrate.

As shown in FIG. 13 to FIG. 15, in some embodiments, the first signal line 31 includes a reference signal line Vref, the reference signal line Vref includes at least a portion extending in the first direction, and the reference signal line Vref is respectively coupled to each sub-pixel driving circuit in a corresponding column of sub-pixel driving circuit columns.

Exemplarily, the display substrate further includes a plurality of second initialization signal lines Vinit2, the second initialization signal line Vinit2 includes at least a portion extending in the second direction, and the second initialization signal line Vinit2 is respectively coupled to each sub-pixel driving circuit in a corresponding row of sub-pixel driving circuit rows.

Exemplarily, the reference signal line Vref and the second source-drain metal layer are arranged in a same layer and made of a same material. The second initialization signal line Vinit2 and the second gate metal layer are arranged in a same layer and made of a same material.

Exemplarily, the plurality of reference signal lines Vref are in one-to-one correspondence with the plurality of columns of sub-pixel driving circuit columns. The plurality of second initialization signal lines Vinit2 are in one-to-one correspondence with the plurality of rows of sub-pixel driving circuit rows.

Since the reference signal line Vref is configured to transmit a reference signal with a stable potential, the reference signal line Vref can well shield crosstalk between two adjacent data lines DA in the data line group 20, thereby effectively improving the display yield and the display quality of the display substrate.

In the foregoing arrangement, the layout of the second initialization signal line Vinit2 and the reference signal line Vref is reasonably planned, which not only reduces the layout difficulty of the signal line, but also ensures the reliability and stability of signal transmission.

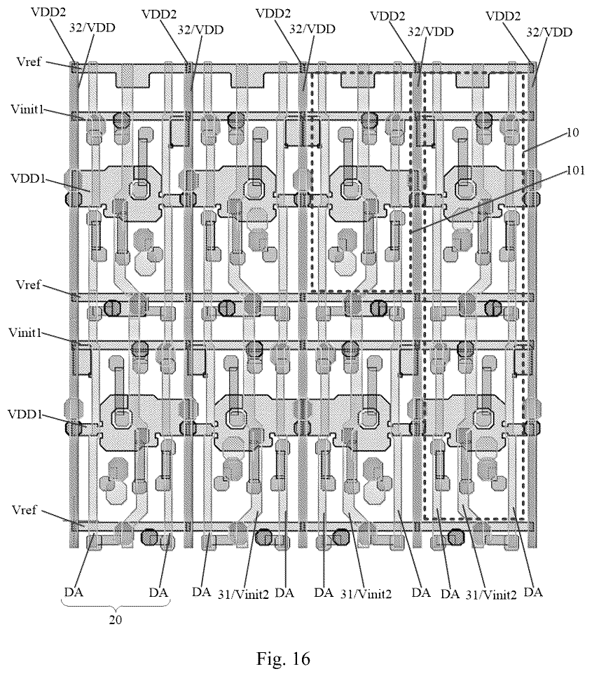

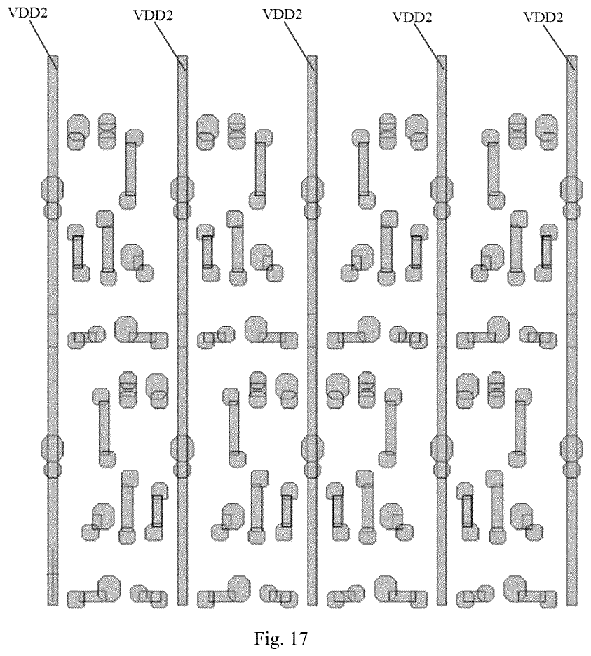

As shown in FIG. 16 to FIG. 18, in some embodiments, the first signal line 31 includes a second initialization signal line Vinit2, the second initialization signal line Vinit2 includes at least a portion extending in the first direction, and the second initialization signal line Vinit2 is respectively coupled to each sub-pixel driving circuit in a corresponding column of sub-pixel driving circuit columns.

Exemplarily, the display substrate further includes a plurality of reference signal lines Vref, the reference signal line Vref includes at least a portion extending in the second direction, and the reference signal line Vref is respectively coupled to each sub-pixel driving circuit in a corresponding row of sub-pixel driving circuit rows.

Exemplarily, the second initialization signal line Vinit2 and the second source-drain metal layer are arranged in a same layer and made of a same material. The reference signal line Vref and the second gate metal layer are arranged in a same layer and made of a same material.

Exemplarily, the plurality of second initialization signal lines Vinit2 are in one-to-one correspondence with the plurality of columns of sub-pixel driving circuit columns. The plurality of reference signal lines Vref are in one-to-one correspondence with the plurality of rows of sub-pixel driving circuit rows.

Since the second initialization signal line Vinit2 is configured to transmit a second initialization signal with a stable potential, the second initialization signal line Vinit2 can well shield crosstalk between two adjacent data lines DA in the data line group 20, thereby effectively improving the display yield and the display quality of the display substrate.

In the foregoing arrangement, the layout of the second initialization signal line Vinit2 and the reference signal line Vref is reasonably planned, which not only reduces the layout difficulty of the signal line, but also ensures the reliability and stability of signal transmission.

As shown in FIG. 4 to FIG. 18, in some embodiments, the plurality of sub-pixel driving circuits are divided into a plurality of rows of sub-pixel driving circuit rows, the display substrate further includes a plurality of first initialization signal lines Vinit1, the first initialization signal line Vinit1 extends in a second direction, and the first initialization signal line Vinit1 is respectively coupled to each sub-pixel driving circuits in a corresponding row of sub-pixel driving circuit rows.

Exemplarily, the plurality of first initialization signal lines Vinit1 are in one-to-one correspondence with the plurality of rows of sub-pixel driving circuits, and the first initialization signal line Vinit1 is respectively coupled to a first electrode of the first reset transistor included in each sub-pixel driving circuit in a corresponding row of sub-pixel driving circuit rows.

Exemplarily, the first initialization signal line Vinit1 and the second gate metal layer are arranged in a same layer and made of a same material.

Embodiments of the present disclosure also provide a display device, including the display substrate provided by the foregoing embodiments.

It should be noted that the display device can be: any product or component having a display function, such as a television, a monitor, a digital photo frame, a mobile phone, a tablet computer, etc., where the display device further includes a flexible circuit board, a printed circuit board, and a back plate, etc.

In the display substrate provided in the foregoing embodiment, a dual data link (DDL) technology is used, so that each column of sub-pixel driving circuit columns corresponds to two data lines DA. One data line DA is configured to provide a data signal for the odd-numbered sub-pixel driving circuit, and the other data line DA is configured to provide a data signal for the even-numbered sub-pixel driving circuit, so that each sub-pixel driving circuit has sufficient charging time, and it is ensured that the display substrate can reduce power consumption of a chip used for providing a data signal in the display substrate while achieving high-frame-frequency display. Moreover, in the display substrate provided by the above embodiment, the sub-pixel driving circuit adopts an LTPS circuit structure, so that the display substrate can realize a low-cost and low-frequency driving mode. In the display substrate provided by the foregoing embodiment of the present disclosure, DDL technology and LTPS technology are combined, so that power consumption is greatly reduced while low-cost and full-frame-frequency driving (that is, low-frame-frequency driving and high-frame-frequency driving can be achieved) are achieved. In addition, in the display substrate provided in the foregoing embodiment, at least a portion of an orthographic projection of the first signal line 31 on the base substrate is arranged between orthographic projections of two adjacent data lines DA in the corresponding data line group 20 on the base substrate. Since the first signal line 31 is configured to transmit a first signal with a stable potential, the first signal line 31 can well shield crosstalk between two adjacent data lines DA in the data line group 20, thereby effectively improving the display yield and display quality of the display substrate.

The display devices provided by embodiments of the present disclosure also have the foregoing beneficial effects when including the foregoing display substrate. Details are not further described herein.

It should be noted that a signal line extending along a X direction means: the signal line includes a main portion and a secondary portion connected to the main portion, the main portion is a line, a line segment or a strip-shaped body, the main portion extends along a X direction, and the length of the main portion extending along a X direction is greater than the length of the secondary portion extending along other directions.

It should be noted that “the same film layer” in an embodiment of the present disclosure may refer to a film layer located on the same structural layer. Alternatively, for example, the film layer at the same level may be a film layer formed to have a particular pattern by using the same film-forming process. The film layer may then be patterned by one patterning process using the same mask to form the desired layer structure. Depending on different particular patterns, the one patterning process may include multiple exposing, developing, or etching processes. Further, as an example, a particular pattern in the formed layer structure may be continuous or discontinuous. As other example, these particular patterns may be at different heights or have different thicknesses.

In the method embodiments of the invention, the sequential number of each step is not used to limit the order of the steps. Instead, the order of the steps may be changed by those skilled in the art without any inventive effort and is thus under the protection of the invention.

It should be noted that the various embodiments in the present description are described in a progressive manner, and the various embodiments may refer to each other for the same or similar parts, and each embodiment focuses on differences from other embodiments. Especially, for the method embodiment, since it is basically similar to the product embodiment, the description is relatively simple, and the relevant parts can be referred to the description of the product embodiment.

Unless otherwise defined, technical terms or scientific terms used in the present disclosure shall have the common meanings understood by those with ordinary skills in the field to which the present disclosure belongs. “First”, “second” and similar words used in the present disclosure do not indicate any order, quantity, or importance, but are only used to distinguish different components. “Include” or “include” and other similar words mean that the element or item before the word encompasses the element or item and their equivalents listed after the word, but does not exclude other elements or items. Similar words such as “coupled” or “connected” are not limited to physical or mechanical connections, but may include electrical connections, whether direct or indirect. “Up”, “down”, “left”, “right”, etc. are only used to indicate a relative position relationship. When an absolute position of a described object changes, the relative position relationship may also change accordingly.

It should be appreciated that, in the case that such an element as layer, film, region or substrate is arranged “on” or “under” another element, it may be directly arranged “on” or “under” the other element, or an intermediate element may be arranged therebetween. In descriptions of the implementation modes, the specific features, structures, materials, or characteristics described may be combined in any suitable manner in any one or more embodiments or examples.

The foregoing are only specific embodiments of the present disclosure, but the protection scope of the present disclosure is not limited thereto. In the technical scope disclosed by the present disclosure, changes or substitutions easily thought by any skilled in the art are all covered in the protection scope of the present disclosure. Therefore, the protection scope of the present disclosure should be the protection scope of the claims.

1. A display substrate, comprising: a base substrate, a plurality of sub-pixels and data lines on the base substrate;
wherein the sub-pixel comprises a sub-pixel driving circuit, a plurality of sub-pixel driving circuits comprised in the plurality of sub-pixels are distributed in an array, and the plurality of sub-pixel driving circuits are divided into a plurality of columns of sub-pixel driving circuit columns;
the plurality of data lines are divided into a plurality of groups of data line groups, the data line group comprises two adjacent data lines; one data line in the data line group is respectively coupled to odd-numbered sub-pixel driving circuits in a corresponding column of sub-pixel driving circuit columns, and the other data line in the data line group is respectively coupled to even-numbered sub-pixel driving circuits in a corresponding column of sub-pixel driving circuit columns;
the display substrate further comprises a plurality of first signal lines configured to transmit a first signal with a stable potential, at least a portion of an orthographic projection of the first signal line on the base substrate is located between orthographic projections of two adjacent data lines in the corresponding data line group on the base substrate.

2. The display substrate according to claim 1, wherein the display substrate further comprises a plurality of second signal lines configured to transmit a second signal with a stable potential, at least a portion of an orthographic projection of the second signal line on the base substrate is located between orthographic projections of two adjacent data lines in different data line groups on the base substrate.

3. The display substrate according to claim 2, wherein the first signal line is close to a middle region of a layout region where a corresponding column of sub-pixel driving circuits columns is located, one data line in the data line group is close to a first side region of a layout region where a corresponding column of sub-pixel driving circuits columns is located, the other data line in the data line group is close to a second side region of a layout region where a corresponding column of sub-pixel driving circuits columns is located, and the middle region is located between the first side region and the second side region.

4. The display substrate according to claim 3, wherein the second signal line comprises a reference signal line, the reference signal line comprises at least a portion extending in a first direction, at least a portion of the reference signal line and a layout region of the sub-pixel driving circuit columns are alternately arranged in a second direction, and the reference signal line is coupled to a corresponding sub-pixel driving circuit.

5. The display substrate according to claim 4, wherein,
the reference signal line comprises a reference signal main body portion and a plurality of reference signal connection portions, the plurality of reference signal connection portions are respectively coupled to the reference signal main body portion, the reference signal main body portion comprises at least a portion extending in the first direction, and the reference signal main body portion and the layout region of the sub-pixel driving circuit columns are alternately arranged in the second direction;
the plurality of reference signal lines in the display substrate comprise a first-type reference signal line, a second-type reference signal line, a third-type reference signal line, and a fourth-type reference signal line;
the first-type reference signal line is respectively coupled to odd-numbered sub-pixel driving circuits in a sub-pixel driving circuit column adjacent to a first side of the first-type reference signal line, and the first-type reference signal line is respectively coupled to odd-numbered sub-pixel driving circuits in a sub-pixel driving circuit column adjacent to a second side of the first-type reference signal line;
the second-type reference signal line is respectively coupled to even-numbered sub-pixel driving circuits in a sub-pixel driving circuit column adjacent to a first side of the second-type reference signal line, and the second-type reference signal line is respectively coupled to odd-numbered sub-pixel driving circuits in a sub-pixel driving circuit column adjacent to a second side of the second-type reference signal line;
the third-type reference signal line is respectively coupled to even-numbered sub-pixel driving circuits in a sub-pixel driving circuit column adjacent to a first side of the third-type reference signal line, and the third-type reference signal line is respectively coupled to even-numbered sub-pixel driving circuits in a sub-pixel driving circuit column adjacent to a second side of the third-type reference signal line;
the fourth-type reference signal line is respectively coupled to odd-numbered sub-pixel driving circuits in a sub-pixel driving circuit column adjacent to a first side of the fourth-type reference signal line, and the second-type reference signal line is respectively coupled to an even-numbered sub-pixel driving circuit in a sub-pixel driving circuit column adjacent to a second side of the second-type reference signal line.

6. The display substrate according to claim 4, wherein the plurality of sub-pixel driving circuits are divided into a plurality of rows of sub-pixel driving circuit rows, the display substrate further comprises a plurality of second initialization signal lines, the second initialization signal line extends in the second direction, and the second initialization signal line is respectively coupled to each sub-pixel driving circuit in a corresponding row of sub-pixel driving circuit rows.

7. The display substrate according to claim 3, wherein the second signal line comprises a reference signal line and a second initialization signal line, the reference signal line comprises at least a portion extending in a first direction, the reference signal line is coupled to a corresponding sub-pixel driving circuit, the second initialization signal line comprises at least a portion extending in the first direction, and the second initialization signal line is coupled to a corresponding sub-pixel driving circuit;
at least a portion of the reference signal line and at least a portion of the second initialization signal line are alternately arranged in a second direction, at least a portion of the layout region of the sub-pixel driving circuit columns is located between the adjacent reference signal line and second initialization signal line.

8. The display substrate according to claim 7, wherein the plurality of reference signal lines in the display substrate comprise a fifth-type reference signal line;
the fifth-type reference signal line is respectively coupled to each sub-pixel driving circuit in a sub-pixel driving circuit column adjacent to a first side of the fifth-type reference signal line, and the fifth-type reference signal line is respectively coupled to each sub-pixel driving circuit in a sub-pixel driving circuit column adjacent to a second side of the fifth-type reference signal line.

9. The display substrate according to claim 7, wherein the plurality of sub-pixel driving circuits are divided into a plurality of rows of sub-pixel driving circuit rows, the display substrate further comprises a plurality of second compensation initialization lines, the second compensation initialization line comprises at least a portion extending in the second direction, and the second compensation initialization line is respectively coupled to each sub-pixel driving circuit in a corresponding row of sub-pixel driving circuit rows;
the second initialization signal line is respectively coupled to the plurality of second compensation initialization lines.

10. The display substrate according to claim 2,
wherein the display substrate further comprises a cathode layer and a plurality of cathode compensation lines, the cathode compensation line comprises at least a portion extending in the first direction, and the cathode compensation line is coupled to the cathode layer;
an orthographic projection of the cathode compensation line on the base substrate and the orthographic projection of the first signal line on the base substrate are alternately arranged in the second direction.

11. The display substrate according to claim 10, wherein the orthographic projection of the cathode compensation line on the base substrate at least partially overlaps with the orthographic projection of the second signal line on the base substrate.

12. The display substrate according to claim 1,
wherein the first signal line comprises a power line, the power line comprises at least a portion extending in the first direction, the power line is respectively coupled to each sub-pixel driving circuit in a corresponding column of sub-pixel driving circuit columns, the display substrate further comprises a plurality of first power compensation lines, the first power compensation line comprises at least a portion extending in the second direction, at least a portion of the first power compensation line is located between the base substrate and the power line, and the first power compensation line is coupled to the power line.

13. The display substrate according to claim 3, wherein the plurality of sub-pixel driving circuits are divided into a plurality of rows of sub-pixel driving circuit rows, the second signal line comprises a power line, the power line comprises at least a portion extending in a first direction, the display substrate further comprises a plurality of first power compensation lines, the first power compensation line comprises at least a portion extending in a second direction, the first power compensation line is respectively coupled to each sub-pixel driving circuit in a corresponding row of sub-pixel driving circuit rows, at least a portion of the first power compensation line is located between the power line and the base substrate, and the power line is respectively coupled to the plurality of first power compensation lines.

14. The display substrate according to claim 13, wherein the display substrate further comprises a plurality of second power compensation lines, the second power compensation line comprises at least a portion extending in the first direction, and at least a portion of the second power compensation line is located between the first power compensation line and the power line;
an orthographic projection of the second power compensation line on the base substrate at least partially overlaps with an orthographic projection of the corresponding power line on the base substrate, and the second power compensation line is respectively coupled to the corresponding power line and the plurality of first power compensation lines.

15. The display substrate according to claim 13, wherein the first signal line comprises a reference signal line, the reference signal line comprises at least a portion extending in the first direction, and the reference signal line is respectively coupled to each sub-pixel driving circuit in a corresponding column of sub-pixel driving circuit columns.

16. The display substrate according to claim 15, wherein the display substrate further comprises a plurality of second initialization signal lines, the second initialization signal line comprises at least a portion extending in the second direction, and the second initialization signal line is respectively coupled to each sub-pixel driving circuit in a corresponding row of sub-pixel driving circuit rows.

17. The display substrate according to claim 13, wherein the first signal line comprises a second initialization signal line, the second initialization signal line comprises at least a portion extending in the first direction, and the second initialization signal line is respectively coupled to each sub-pixel driving circuit in a corresponding column of sub-pixel driving circuit columns.

18. The display substrate according to claim 17, wherein the display substrate further comprises a plurality of reference signal lines, the reference signal line comprises at least a portion extending in the second direction, and the reference signal line is respectively coupled to each sub-pixel driving circuit in a corresponding row of sub-pixel driving circuit rows.

19. The display substrate according to claim 1, wherein the plurality of sub-pixel driving circuits are divided into a plurality of rows of sub-pixel driving circuit rows, the display substrate further comprises a plurality of first initialization signal lines, the first initialization signal line extends in a second direction, and the first initialization signal line is respectively coupled to each sub-pixel driving circuits in a corresponding row of sub-pixel driving circuit rows.

20. A display device, comprising a display substrate according to claim 1.
